(19) United States
(12) Patent Application Publication
(10) Pub. No.: US 2013/0321040 A1
(43) Pub. Date: Dec. 5, 2013

(54) METHOD AND SYSTEM FOR USING DEMAND RESPONSE TO PROVIDE FREQUENCY REGULATION

(71) Applicants: Harjeet Johal, Glenville, NY (US); Krishna Kumar Anaparthi, Bayern (DE); Jason Wayne Black, Dublin, OH (US)

(72) Inventors: Harjeet Johal, Glenville, NY (US); Krishna Kumar Anaparthi, Bayern (DE); Jason Wayne Black, Dublin, OH (US)

(73) Assignee: GENERAL ELECTRIC COMPANY, SCHENECTADY, NY (US)

(21) Appl. No.: 13/485,448

(22) Filed: May 31, 2012

(51) Int. Cl. H03L 7/00

(52) U.S. Cl. 327/113

(57) ABSTRACT

A frequency regulation system includes a sensor to detect a power grid signal and a frequency deviation identification module to determine a power grid frequency deviation from the power grid signal. A demand response module identifies an operating schedule for available demand response resources based on frequency deviation set points and ramp rates and a load control module controls the available demand response resources based on the operating schedule.

### BACKGROUND

Embodiments of the system relate generally to an electric power system and more specifically to regulation of a power system frequency.

Power system frequency is a major indicator of the power balance in the power system. A decrease in power generation in relation to the demand or load causes the frequency to drop and may drop below a nominal frequency. Similarly, a decrease in demand with a certain power level causes the frequency to increase and may increase beyond the nominal frequency. Furthermore, high penetration of intermittent energy sources such as wind turbines increases the potential for variability in system frequency.

If the frequency deviates too far from the nominal frequency, equipment like pumps and motors run faster at the higher frequencies or slower at the lower frequencies. Some equipment will even shut down to avoid getting damaged. Even clocks will run faster or slower. A sharp decline in frequency was one reason that the Northeast blackout of August 2003 spread as quickly as it did and affected an estimated 10 million people. Mainly because of the sharp decline in the frequency in relation to the power fluctuations, many under frequency load shedding controllers operated to disconnect some or all of the loads.

To ensure a functional and reliable grid, the Independent System Operators (ISOs) that operate the various regional grids must maintain their electric frequency very close to 60 hertz (Hz), or cycles per second (50 Hz in certain countries). Grid operators, therefore, seek to continuously balance power generation with demand to maintain the proper frequency. The imbalance between power generation and demand can be mitigated by a primary control and a secondary control of conventional synchronous generators.

Not all generators can operate reliably in such a variable way. Changing power output causes greater wear and tear on equipment, and generators that perform frequency regulation incur higher operating costs due to increased fuel consumption and maintenance costs. They also suffer a significant loss in “heat rate” efficiency and produce greater quantities of CO2 and other unwanted emissions when throttling up and down to perform frequency regulation services.

For these and other reasons, there is a need for improved frequency regulation.

### BRIEF DESCRIPTION

In accordance with an embodiment of the present invention, a frequency regulation system is provided. The system includes a sensor to detect a power grid signal and a frequency deviation identification module to determine a power grid frequency deviation from the power grid signal. The system also includes a demand response module to identify an operating schedule for available demand response resources based on frequency deviation set points and ramp rates and a load control module to control the available demand response resources based on the operating schedule.

In accordance with another embodiment of the present invention, a method of regulating a system frequency is provided. The method includes measuring a system frequency deviation and providing frequency deviation set points to demand response resources. The method also includes providing an adjustable ramp rate response from demand response resources based on the system frequency deviation.

In accordance with yet another embodiment of the present invention, a frequency regulation system is provided. The frequency regulation system includes an error detection module to detect an area control error (ACE) for a balancing area and an allocation module to allocate the ACE among generating units and demand response resources in the balancing area. The frequency regulation system also includes a demand response module to identify an operating schedule for the demand response resources based on frequency deviation set points and ramp rates and a load control module to control the available demand response resources based on the operating schedule.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic diagram of power generation system;

FIG. 2 is a graphical diagram of a frequency droop curve;

FIG. 3 is a schematic diagram of a distribution system in accordance with an embodiment of the present system;

FIG. 4 is another schematic diagram of a distribution system in accordance with an embodiment of the present system;

FIG. 5 is a block diagram of a detailed centralized frequency regulation system utilized in coordination with an automatic generation control (AGC) system in accordance with an embodiment of the present system;

FIG. 6 is a graphical diagram illustrating various modes of the frequency regulation system of FIG. 5;

FIG. 7 is a block diagram of a frequency regulation system illustrating coordination between a central controller and a local controller in accordance with an embodiment of the present system; and

FIG. 8 is a flow chart illustrating a method of regulating a system frequency in accordance with one embodiment.

### DETAILED DESCRIPTION

As used herein, the terms “controller” or “module” refers to software, hardware, or firmware, or any combination of these, or any system, process, or functionality that performs or facilitates the processes described herein.

When introducing elements of various embodiments of the present invention, the articles “a,” “an,” “the,” and “said” are intended to mean that there are one or more of the elements. The terms “comprising,” “including,” and “having” are intended to be inclusive and mean that there may be additional elements other than the listed elements.

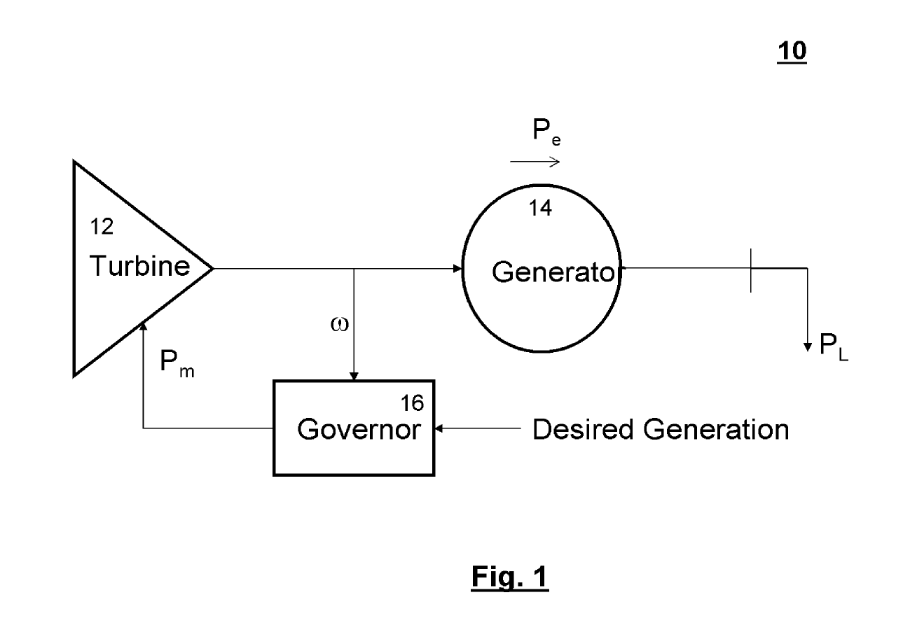

FIG. 1 shows one example of a power generation system 10. Power generation system 10 includes a turbine 12, a generator 14 and a governor 16. The turbine 12 and the generator 14 are connected to a common shaft (not shown). Thus, when the turbine 12 spins, generator 14 converts the mechanical spinning energy into electrical energy. During a stable operation, a turbine mechanical power (Pₘ) and an electrical load power (P_{L}) are approximately equal. Whenever there is a change in electrical load power P_{L} with turbine mechanical power Pₘ remaining the same, an angular frequency or speed (ω) of the turbine generator changes as decided by a rotating inertia (M) of the turbine-generator system, as given by the following differential equation:

Pₘ−P_{L}=M[dω/dt] (1)

Governor 16 senses this change in speed and adjusts a steam control valve (not shown) of turbine 12 so that mechanical power (Pₘ) matches with the changed load (P_{L}). For example, when frequency increases, governor 16 controls the steam control valve so as to decrease the steam input to turbine 12 and vice versa. This is generally called as a primary frequency control.

It should be noted that even though the example shown is for a single turbine-generator system, it also applies to a power system including several turbine-generators. In such a case, Pₘ will be a combined mechanical power of all turbines and P_{L} will be a total electrical load of the power system. Similarly, M will be the total inertia of all rotating components.

Following primary frequency control (i.e., governor action), when Pₘ is equal to P_{L}, frequency variation (dω/dt) stops but the frequency ω settles down to a different steady state value. The change in frequency (Δω) at a steady state can be described using the following equation in terms of change in a power imbalance (ΔP₁) and a factor R called ‘speed regulation or ‘droop’.

Δω=−ΔP₁/(D+1/R)=−ΔP₁/B₁ (2)

where D is a damping factor and power imbalance ΔP₁ may be either because of drop in power generation (e.g., wind, solar) or increase in load.

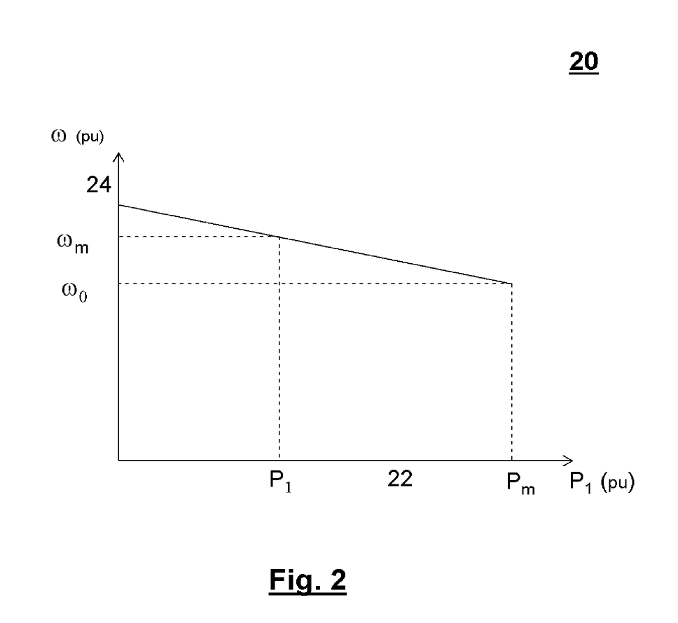

FIG. 2 shows a frequency droop curve 20. A horizontal axis 22 represents power P in per unit (pu) and a vertical axis 24 represents frequency ω in pu. A slope of frequency droop curve is given as Δω/ΔP₁=(ω₀−ωₘ)/(P₀−Pₘ) which is equivalent to 1/B₁ in equation 2. Assuming, D=1 and R=0.05, for a pu change in power ΔP_{L} the frequency ω will change by 0.0476 pu i.e. 2.856 Hz for 60 Hz standard frequency. As will be appreciated by those skilled in the art, per unit is an expression of system quantities as fractions of a defined base unit quantity.

After primary frequency control, once the frequency or the speed settles down to a new value, it is necessary to bring it back to the original value. This is desired because inertial energy of rotating elements depends on frequency ω and since the frequency has moved to a new value, the inertial energy may also increase or decrease resulting in continuous increase or decrease of frequency. A secondary frequency control such as an automatic generation control (AGC) (not shown) is used in power generation system 10 to bring the frequency to an original value. It can be seen from FIG. 2 and equation 2 that the frequency can be changed in two ways 1) by increasing or decreasing the power generation (AGC as defined earlier) or 2) by decreasing or increasing the load (demand). In accordance with an embodiment of the present invention, a frequency control (which can participate as primary or secondary) system utilizing demand response is employed.

The secondary frequency control system utilizing demand response may work along with the AGC operation or after the AGC operation or even before AGC operation. By enabling demand response to decrease load consumption, the secondary control system will reduce the effort needed on the side of generators and will also help in a faster recovery or restoration of system frequency. The value of using demand response for frequency regulation may be more important with high penetration of intermittent renewable energy on the power system.

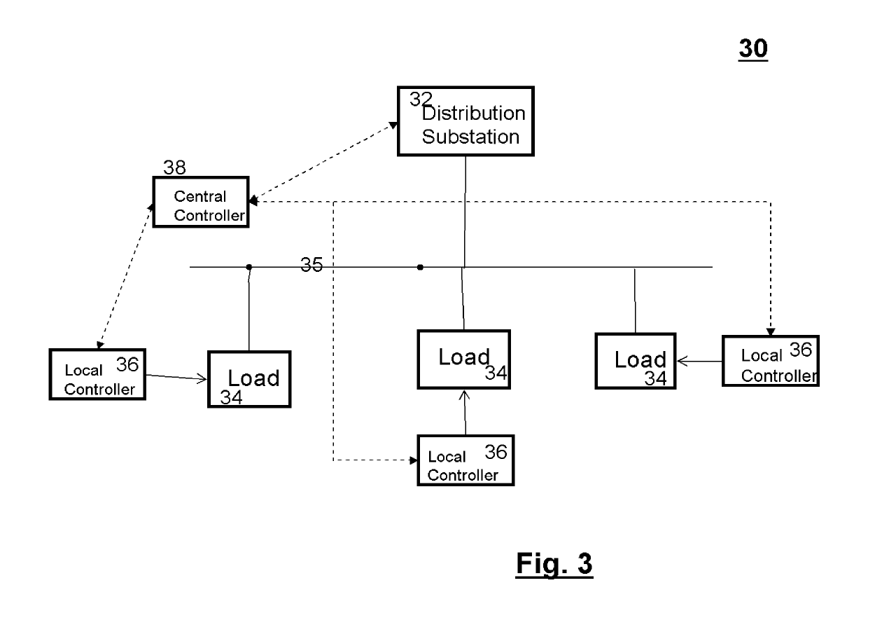

FIG. 3 is a distribution system 30 (within a balancing area) in accordance with an embodiment of the present system. Distribution system 30 includes a distribution substation 32, a plurality of loads 34 with respective local controllers 36 and a central controller 38. Distribution substation 32 supplies electricity to loads 34 which may include residential, industrial or commercial loads through a feeder 35. Local controller 36 may include a relay or similar other circuit which disconnects or reconnects load or demand response (DR) resource 34 from feeder 35 based on a signal from central controller 38.

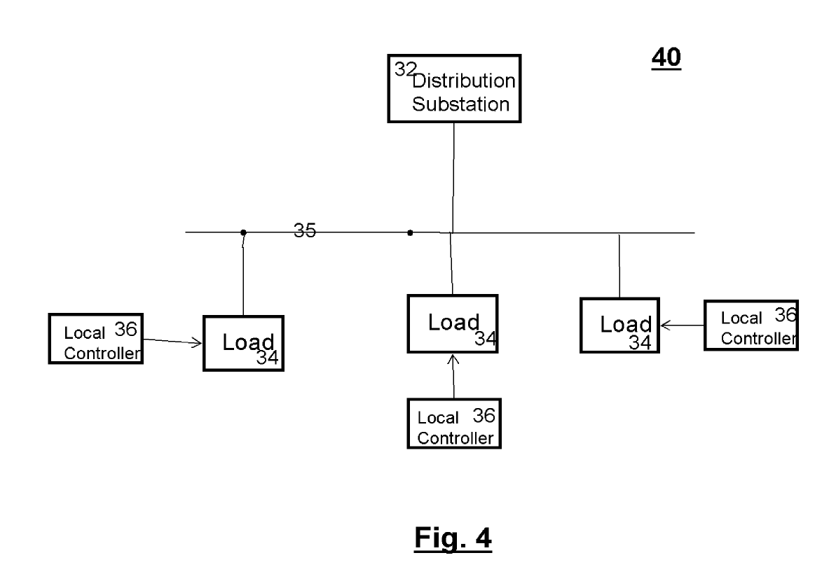

Central controller 38 provides control signals to local controllers 36 to control demand response resources 34. The signal from central controller 38 is determined based on the frequency deviation. Central controller 38 may also be a part of another controller such as supervisory control and data acquisition (SCADA) system (not shown) which is utilized for operation and maintenance of distribution system 30. In one embodiment, local controllers 36 may be smart meters which facilitate communication between loads 34 and central controller 38. The communication modes between central controller 38 and local controllers 36 can include fiber optics, power line carrier systems, and various wireless technologies. For ease of discussion, only one central controller 38 is shown, however, there can be any number of central controllers 38 in distribution system 30. It should be noted that even though central controller 38 and local controller 36 are shown to be two separate components, in one embodiment 40 as shown in FIG. 4, the functionalities of central controller 38 may be incorporated in each of local controllers 36. Such an embodiment can be called as distributed control. In this embodiment, the local controller 36 will be more complex but operating independently.

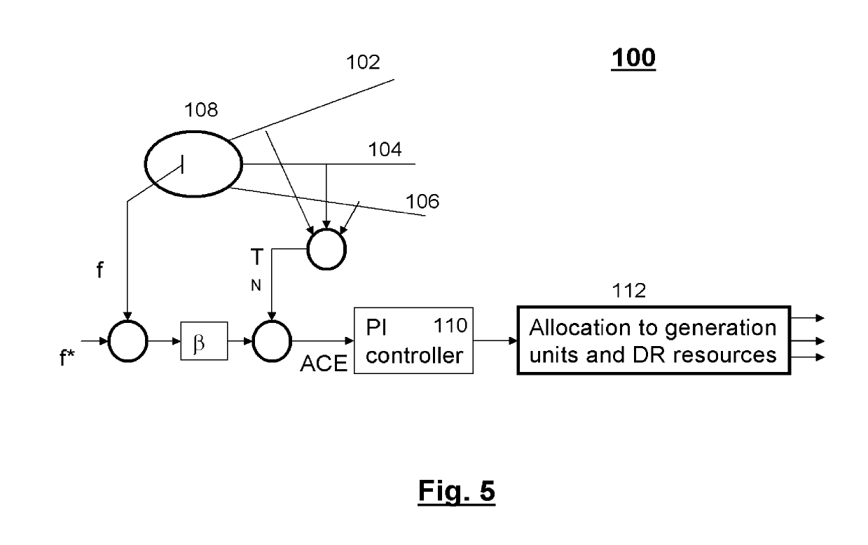

FIG. 5 is a detailed centralized frequency regulation system 100 employing demand response utilized in coordination with an AGC system in accordance with an embodiment of the present invention. In centralized frequency regulation system 100, frequency is regulated by controlling load power of DR resources or power generation of generating units. Various balancing areas shown by lines 102, 104, and 106 in a power grid are connected by a tie line 108 and interchange power with each other. For each of the areas 102, 104, and 106, a tie line error T_{N} which is a difference between actual and scheduled net power interchange for a given balancing area on the tie line is determined. The tie line error T_{N} for each area is then modified by a frequency deviation term β(f*−f), where β is a constant, f* is a scheduled frequency and f is an actual frequency to obtain an area control error (ACE). The constant β depends on governor response of generating units in the balancing area. The ACE is then fed to a proportional-integral (PI) controller 110 which helps in making ACE zero. It should be noted that PI controller 110 is shown only for exemplary purpose and in other embodiments any other suitable controller may be used. When ACE is negative power generation of generating units in that particular area is increased or load power of DR resources is curtailed and vice versa. When all areas have zero ACE then frequency deviation will be zero. An output signal of PI controller 110 is then utilized by an allocation unit 112 to determine contribution of each generating unit and Demand resources. It should be noted that ACE in turn represents frequency deviation, thus, in another embodiment, frequency deviation set points may be utilized for distinguishing between AGC system and DR resources control.

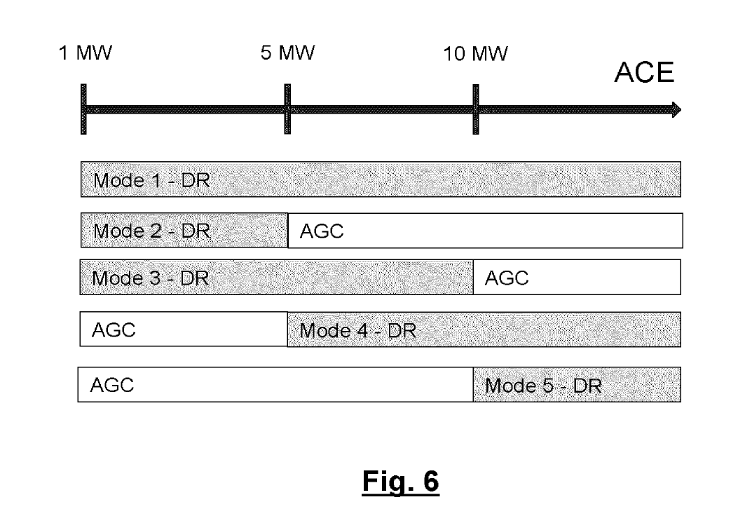

FIG. 6 shows various modes of an exemplary frequency regulation system 100 of FIG. 5. In mode 1, the entire ACE of a balancing area is compensated by DR resources whereas in mode 2 and mode 3, first 5 MW and 10 MW of the ACE respectively is compensated by DR resources and remaining ACE is supplied by a AGC system. On the contrary, in mode 4 and mode 5, first 5 MW and 10 MW of the ACE are compensated by AGC system respectively and remaining ACE is compensated by DR resources. In some embodiments, the power to be compensated by DR resources is not fixed, rather the AGC system will merely wait for a delay time within which available DR resources will contribute to frequency regulation and then after the delay time AGC will try to compensate for remaining ACE. In such embodiments, distributed control may also be employed as local controllers will first respond to frequency deviation and then the AGC system will operate for later duration.

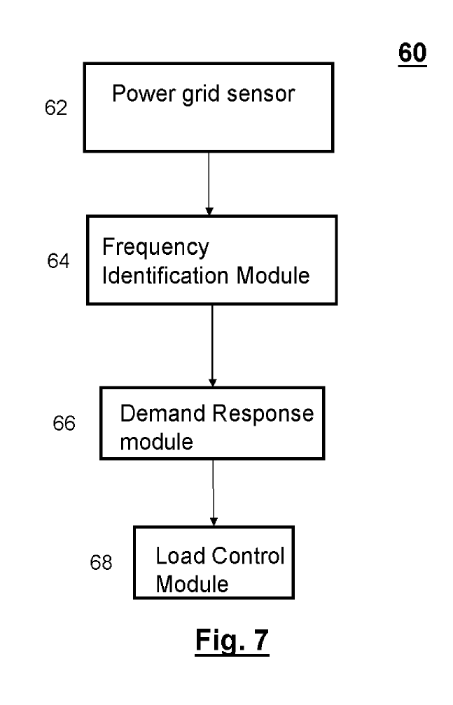

FIG. 7 is a frequency regulation system 60 illustrating coordination between central controller 38 and local controller 36 in accordance with an embodiment of the present system. As discussed herein, functionalities of central controller 38 may also be incorporated in local controller 36 and thus frequency regulation system 60 may also be considered as a local controller 36. Frequency regulation system 60 includes a power grid sensor 62 which senses a power grid signal. The power grid signal may include a line voltage and/or a line current. Power grid sensor 62 may include a voltage or a current transformer to reduce the strength of the signal. The power grid signal is then analyzed by a frequency deviation identification module 64. Frequency deviation identification module 64 determines a frequency deviation Δ for Δω from the power grid signal. Frequency deviation identification module 64 may be based on techniques such as zero-crossing, discrete Fourier transform, least-square-error, Kalman filtering, phasor demodulation, Newton algorithm, Prony algorithm, and Taylor method.

As discussed above, the frequency deviation is directly related to power change in the power grid. The power change may be because of fluctuations in renewable power generation such as wind and solar. Thus, a demand response module 66 determines an operating schedule for available demand response resources for the period of interest and utilizes it to compensate for the frequency deviation based on frequency deviation set points and ramp rates which will be described in more detail in subsequent paragraphs. Demand response refers to mechanisms used to encourage/induce utility consumers to curtail or shift their individual demand in order to reduce aggregate utility demand during particular time periods. For example, in the present embodiment, electric utilities employ demand response programs to regulate the frequency. Demand response programs typically offer customers incentives for agreeing to reduce their demand during certain time periods as per specific contractual obligation. For example, a contract may specify that the utility can invoke up to 15 events per year, where each event will occur between the hours of 12 pm and 6 pm with a maximum of 60 total hours per year. According to embodiments of the invention, the utility can choose to use 10 events of 6 hours each, or 15 events of 4 hours each to balance the load, or any other such combination of events and hours to stay within the 15 events, 60 hours limitations for each customer.

In an example, assume that demand response module 66 determines that Δf determined by frequency deviation identification module 64 is such that it corresponds to a 5 MW power error. Then in one embodiment, DR module 66 can schedule a sampling time of 5 secs (meaning after 5 sec a load change or demand response of 5 MW will be available, corresponding to a ramp rate of 1 MW/sec). In another embodiment, the demand response can be on a slower sampling time of 10 sec, thus corresponding to a ramp rate of 0.5 MW/sec. In one embodiment, the ramp rate or the delay in reacting to MW requirement can be based upon pre-programmed frequency deviation thresholds or set points. A lower ramp rate (or a greater delay) for small frequency deviations and a larger ramp rate (or a smaller delay) for bigger frequency deviations. Thus, the ramp rates are directly proportional to frequency deviations. In one embodiment, the relationship between the ramp rate and the frequency deviation may be determined by the system operator such that the demand response to frequency has the appropriate control gain when operating in conjunction with the AGC frequency deviation response. This will depend largely on the composition of generators participating in AGC and the percentage of secondary control that is provided by demand response. A load control module 68 then actually controls the load or demand response resources based on the operating schedule determined by DR module 66.

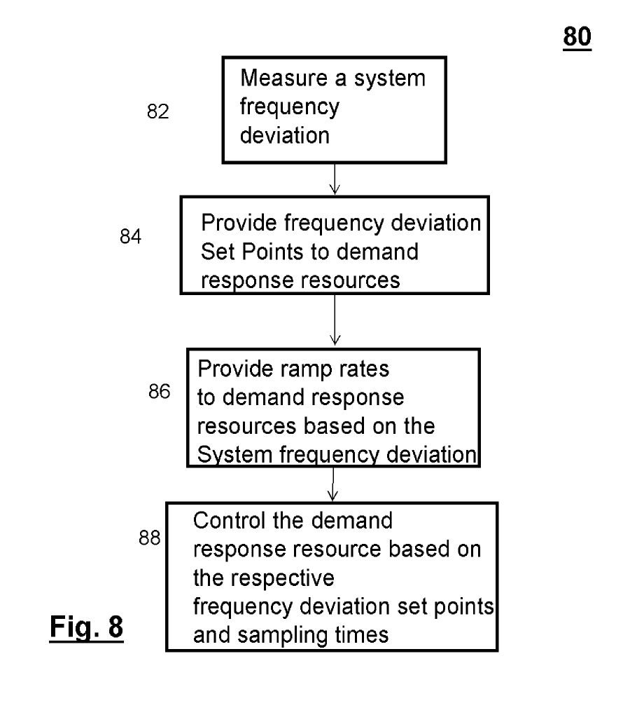

FIG. 8 shows a method 80 of regulating a system frequency in accordance with an embodiment of the present system. The method 80 includes measuring a system frequency deviation at step 82. In one embodiment, the system frequency deviation may be measured by analyzing a power grid signal such as a line voltage or a line current. The techniques to analyze the power grid signal include zero-crossing, discrete Fourier transform, least-square-error, Kalman filtering, phasor demodulation, Newton algorithm, Prony algorithm, and Taylor method.

At step 84, frequency deviation set points (which can be correlated to a particular error in generating power and load power for a particular power system) are provided for available demand response resources 82. The frequency deviation set points will be different for different groups of demand response resources but can be rotated so that one particular group does not get penalized every time. These frequency deviation set points will be chosen based on how frequently and by how much the operator wants the demand response units to support the frequency regulation. For example, one group of demand response resources can be made active at 0.005 pu whereas for another group could be made active at 0.001 pu. The groups are uniformly distributed in terms of when they respond to frequency deviation so that there is a continuous aggregate response to frequency deviations. In one embodiment, the frequency deviation set points are determined based on the settings of the primary frequency regulation system such as a governor control system. In another embodiment, the frequency deviation set points are determined in conjunction with automatic generation control (AGC) frequency deviation set points as described earlier. Furthermore, the frequency deviation set points may either be preprogrammed in local controllers 36 or may be provided by central controller 38 in real time.

The method 80 further includes a step 86 of providing a ramp rate response from the demand response resources based on the system frequency deviation. The ramp rate response can be translated into to a sampling time or a time delay after which the demand response resource starts participating in the frequency regulation. The ramp rate for each demand response resources is provided such that if there is smaller frequency deviation then ramp rate will be relatively smaller for various participating groups of demand response resources so that a relatively small number of demand response resources will respond over a given time frame to the small frequency deviation. Similarly, for larger frequency deviations, the ramp rate will be set at smaller values so that more demand resources respond in the same given time frame to mitigate the larger imbalance between generation and load. The ramp rates will be set to create the aggregated response ramp rate desired to stabilize system frequency in coordination with other AGC resources. Finally, in step 88, the demand response resources are controlled based on the respective frequency deviation set points and ramp rates.

In one embodiment, the DR resources groups will be formed based on varying ramp rates. In such an embodiment, the ramp rates for DR resources are decided based on the frequency deviation. For example, in one embodiment, first two groups will have the ramp rate corresponding to a sampling time of T1 seconds for the frequency deviation of Apu and T2 seconds for the frequency deviation of B pu per second, whereas for remaining two groups the respective sampling times may be T3 and T4 seconds.

Advantages of embodiments of the disclosed frequency regulation system include a decrease in thermal generator maneuvering and a tighter frequency regulation.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A frequency regulation system comprising:
a sensor to detect a power grid signal;
a frequency deviation identification module to determine a power grid frequency deviation from the power grid signal;
a demand response module to identify an operating schedule for available demand response resources based on frequency deviation set points and ramp rates; and
a load control module to control the available demand response resources based on the operating schedule.

2. The frequency regulation system of claim 1, wherein the frequency deviation set points and ramp rates are provided to the demand response module by a central controller.

3. The frequency regulation system of claim 2, wherein the frequency deviation set points and ramp rates are provided based on a frequency deviation response of an automatic generation control (AGC) system.

4. The frequency regulation system of claim 3, wherein the operating schedule for available demand response resources includes utilizing the demand response resources before or after the AGC operation.

5. The frequency regulation system of claim 1, wherein frequency deviation set points and ramp rates are preprogrammed in the demand response module.

6. The frequency regulation system of claim 1, wherein ramp rates are provided based on the power grid frequency deviation.

7. The frequency regulation system of claim 6, wherein the ramp rate is directly proportional to the power grid frequency deviation.

8. The frequency regulation system of claim 1, wherein the frequency deviation set points and the ramp rates for a plurality of groups of available demand response resources are selected based on an area control error.

9. The frequency regulation system of claim 1, wherein ramp rate values are different for different groups of available demand response resources.

10. The frequency regulation system of claim 9, wherein the ramp rate values for different groups of available demand response resources vary over time.

11. A method of regulating a system frequency comprising:
measuring a system frequency deviation;
providing frequency deviation set points to demand response resources;
providing ramp rates to demand response resources based on the system frequency deviation; and
controlling the demand response resources based on the respective frequency deviation set points and ramp rates.

12. The method of claim 11 wherein, the frequency deviation set points include actual values of system frequency deviation.

13. The method of claim 11 wherein, the demand response resources are divided into a plurality of groups and wherein the frequency deviation set points and the ramp rates for the plurality of groups are selected based on providing a continuous aggregate response to the system frequency deviation.

14. The method of claim 11, wherein the frequency deviation set points are determined based on settings of a primary frequency regulation system or an automatic generation control system settings.

15. The method of claim 11, wherein measuring the system frequency deviation comprises analyzing a voltage signal or a current signal.

16. The method of claim 11, wherein the ramp rate is directly proportional to the system frequency deviation.

17. The method of claim 11, wherein the frequency deviation set points and ramp rates are predetermined or are provided by a central controller.

18. A frequency regulation system comprising:
an error detection module to detect an area control error (ACE) for a balancing area;
an allocation module to allocate the ACE among generating units and demand response (DR) resources in the balancing area;
a demand response module to identify an operating schedule for the demand response resources based on frequency deviation set points and ramp rates; and
a load control module to control the available demand response resources based on the operating schedule.

19. The frequency regulation system of claim 18, wherein the operating schedule includes utilizing the DR resources prior to the generating units.

20. The frequency regulation system of claim 18, wherein the operating schedule includes utilizing the generating units prior to the DR resources.
